(19) United States
(12) Patent Application Publication
(10) Pub. No.: US 2017/0125486 A1
(43) Pub. Date: May 4, 2017

(54) PIXEL UNIT AND METHOD FOR FABRICATING THE SAME, DISPLAY DEVICE

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventor: Wenqiang CHEN, Beijing (CN)

(21) Appl. No.: 15/292,312

(22) Filed: Oct. 13, 2016

(30) Foreign Application Priority Data
Oct. 28, 2015 (CN) 201510714052.X

(51) Int. Cl. H01L 27/32; H01L 51/00; H01L 51/56

(52) U.S. Cl. CPC H01L 27/3209; H01L 27/3213; H01L 27/3216; H01L 51/56; H01L 51/0002; H01L 51/5012

(57) ABSTRACT

Disclosed is a pixel unit, a method for manufacturing the same and a display device. A white sub-pixel unit of the pixel unit includes: a white light carrier injection layer which is formed in a same patterning method as red, green and blue light carrier injection layers; a white light carrier transmission which is formed in a same patterning method as red, green and blue light carrier transmission layers; and a white light organic EL material layer which is formed in a same patterning method as those organic EL material layers corresponding to other sub-pixel units.

### FIELD OF THE ART

Embodiments of the disclosure relate to the technical field of display technologies, more particularly, to a pixel unit and a method for fabricating the same and a display device.

### BACKGROUND

An organic light emitting diode (OLED) display is a display comprising an anode, a cathode and an organic material layer disposed between the anode and the cathode, wherein the organic material layer comprises a hole injection layer, a hole transmission layer, an organic electroluminescence (EL) material layer, an electron transmission layer and an electron injection layer stacked successively one above another. In operation, a driving voltage is applied between the anode and cathode of the OLED display so as to inject electrons and holes into the organic EL material layer through the hole injection layer, the hole transmission layer, the electron transmission layer and the electron injection layer. The electrons and holes recombine in the organic EL material layer, allowing the organic EL material layer to be luminous, thereby realizing a color display of the OLED display.

However, the conventional pixel units need to be evaporated for several times during the fabrication process, thereby increasing the cost.

### SUMMARY

Aspects of the disclosure provide a pixel unit, a method for fabricating the same, and a display device, with an aim of solving the problem that white sub-pixel units need to be evaporated for several times during the fabrication process which causes an increase of evaporation cost.

A aspect of the disclosure provides a pixel unit, which comprises a red sub-pixel unit, a green sub-pixel unit, a blue sub-pixel unit and a white sub-pixel unit; wherein the red sub-pixel unit comprises a red light carrier injection layer, a red light carrier transmission layer and a first red light organic electro luminescence (EL) material layer; the green sub-pixel unit comprises a green light carrier injection layer, a green light carrier transmission layer and a first green light organic EL material layer; the blue sub-pixel unit comprises a blue light carrier injection layer, a blue light carrier transmission layer and a first blue light organic EL material layer; and the white sub-pixel unit comprises a white light carrier injection layer, a white light carrier transmission, a second red light organic EL material layer, a second green light organic EL material layer and a second blue light organic EL material layer; wherein the white light carrier injection layer is formed in a same patterning process as the red light carrier injection layer, the green carrier injection layer and the blue light carrier injection layer; the white light carrier transmission layer is formed in a same patterning process as the red light carrier transmission layer, the green light carrier transmission layer and the blue light carrier transmission layer; the second red light organic EL material layer is formed in a same patterning process as the first red light organic EL material layer; the second green light organic EL material layer is formed in a same patterning process as the first green light organic EL material layer; the second blue light organic EL material layer is formed in a same patterning process as the first blue light organic EL material layer.

Another aspect of the disclosure provides a method for fabricating a pixel unit, and the method comprises forming the red light carrier injection layer, the green carrier injection layer, the blue light carrier injection layer and the white light carrier injection layer in a same patterning process; forming the red light carrier transmission layer, the green light carrier transmission layer, the blue light carrier transmission layer and the white light carrier transmission layer in a same patterning process; forming the first red light organic EL material layer and the second red light organic EL material layer in a same patterning process; forming the first green light organic EL material layer and the second green light organic EL material layer in a same patterning process; forming the first blue light organic EL material layer and the second blue light organic EL material layer in a same patterning process.

Still another aspect of the disclosure provides a display device comprising the above pixel unit.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 schematically illustrates a cross section of a RGBW four colors sub-pixel;

FIG. 2 schematically illustrates a cross section of a RGBW four colors sub-pixel in accordance with an embodiment of the disclosure;

FIG. 3 schematically illustrates a cross section of a white sub-pixel unit in accordance with an embodiment of the disclosure;

FIG. 4 schematically illustrates a cross section of another white sub-pixel unit in accordance with an embodiment of the disclosure;

FIG. 5 schematically illustrates a pixel unit in accordance with an embodiment of the disclosure;

FIG. 6 schematically illustrates a pixel unit in accordance with another embodiment of the disclosure;

FIG. 7 schematically illustrates a pixel unit in accordance with still another embodiment of the disclosure;

FIG. 8 schematically illustrates a pixel unit in accordance with yet another embodiment of the disclosure;

FIG. 9 schematically illustrates a red light organic EL material layer in accordance with an embodiment of the disclosure;

FIG. 10 schematically illustrates a green light organic EL material layer in accordance with an embodiment of the disclosure; and

FIG. 11 schematically illustrates a blue light organic EL material layer in accordance with an embodiment of the disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

FIG. 1 schematically illustrates a cross section of a RGBW four colors sub-pixel. A white sub-pixel unit 4 is formed by a red light organic material layer 1, a green light organic material layer 2 and a blue organic material layer 3 stacked one above another. As each of the red light organic material layer 1, the green light organic material layer 2 and the blue organic material layer 3 comprises a hole injection layer, a hole transmission layer, an electron injection layer and an electron transmission layer, during the fabricating process of the white sub-pixel unit 4, each of the hole injection layers, the hole transmission layers, the electron injection layers and the electron transmission layers of respective organic material layers of the white sub-pixel unit 4 (i.e., the red light organic material layer 1, the green light organic material layer 2 and the blue organic material layer 3) is evaporated separately, causing the white sub-pixel unit 4 of the RGBW four colors sub-pixel structure to be evaporated too many times during the fabricating process.

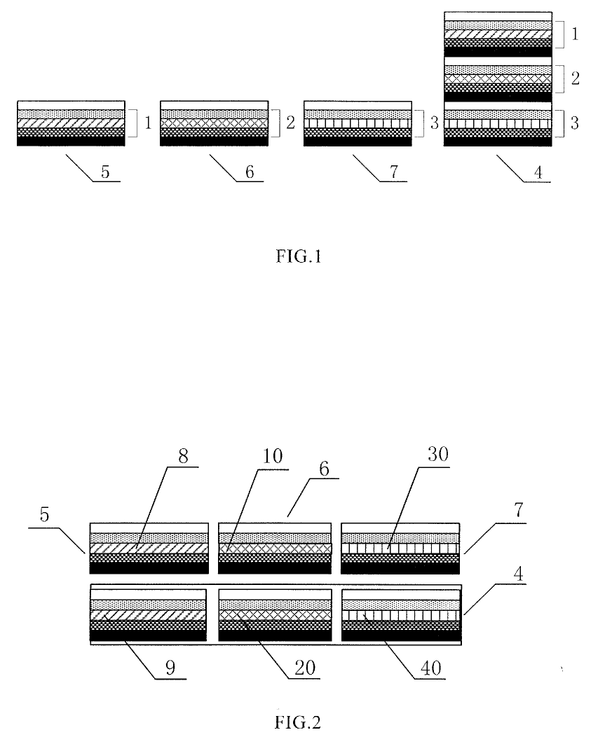

With reference to FIG. 2, a pixel unit provided by an embodiment of the disclosure comprises a red sub-pixel unit 5, a green sub-pixel unit 6, a blue sub-pixel unit 7 and a white sub-pixel unit 4. The red sub-pixel unit 5 comprises a red light carrier injection layer, a red light carrier transmission layer and a first red light organic electroluminescence (EL) material layer 8; the green sub-pixel unit 6 comprises a green light carrier injection layer, a green light carrier transmission layer and a first green light organic EL material layer 10; the blue sub-pixel unit 7 comprises a blue light carrier injection layer, a blue light carrier transmission layer and a first blue light organic EL material layer 30; the white sub-pixel unit 4 comprises a white light carrier injection layer, a white light carrier transmission, a second red light organic EL material layer 9, a second green light organic EL material layer 20 and a second blue light organic EL material layer 40. The white light carrier injection layer is formed by a same patterning process as the red light carrier injection layer, the green carrier injection layer and the blue light carrier injection layer; the white light carrier transmission layer is formed by a same patterning process as the red light carrier transmission layer, the green light carrier transmission layer and the blue light carrier transmission layer; the second red light organic EL material layer 9 is formed by a same patterning process as the first red light organic EL material layer 8; the second green light organic EL material layer 20 is formed by a same patterning process as the first green light organic EL material layer 10; the second blue light organic EL material layer 40 is formed by a same patterning process as the first blue light organic EL material layer 30.

As an example, a patterning process refers to a process comprising steps such as photoresist applying, exposing, developing, etching, and removal of the remaining photoresist. Alternatively, the process may comprise other methods for form a pattern such as ink-jet printing, evaporating, sputtering and the like. In at least some of the embodiments, the various patterned layers formed by a same patterning process are disposed in a same layer. As an example, the white light carrier injection layer, the red light carrier injection layer, the green light carrier injection layer and the blue light carrier injection layer are formed in a same layer; and the white light carrier transmission layer, the red light carrier transmission layer, the green light carrier transmission layer and the blue light carrier transmission layer are formed in a same layer. The second red light organic EL material layer 9 is formed in a same layer as the first red light organic EL material layer 8; the second green light organic EL material layer 20 is formed in a same layer as the first green light organic EL material layer 10; and the second blue light organic EL material layer 40 is formed in a same layer as the first blue light organic EL material layer 30.

During operation, when the pixel unit needs to emit color light, drive voltages are applied to the red sub-pixel unit 5, the green sub-pixel unit 6 and the blue sub-pixel unit 7 respectively. Under the action of the voltages, red light carriers of the red light carrier injection layer go into the first red light organic EL material layer 8 through the red light carrier transmission layer, and recombine in the first red light organic EL material layer 8, allowing the first red light organic EL material layer 8 to emit red light. Similarly, under the action of the voltages, green light carriers of the green light carrier injection layer go into the first green light organic EL material layer 10 through the green light carrier transmission layer, and recombine in the first green light organic EL material layer 10, thereby allowing the first green light organic EL material layer 10 to emit green light; under the action of the voltages, blue light carriers of the blue light carrier injection layer go into the first blue light organic EL material layer 30 through the blue light carrier transmission layer, and recombine in the first blue light organic EL material layer 30, thereby allowing the first blue light organic EL material layer 30 to emit blue light. The emitted red light, green light and blue light are mixed to form a color light.

When the pixel unit needs to emit white light, a voltage is applied to the white sub-pixel unit 4. Under the action of the voltage, white light carriers of the white light carrier injection layer go into the second red light organic EL material layer 9, the second green light organic EL material layer 20 and the second blue light organic EL material layer 40 respectively through the white light carrier transmission layer, and recombine in the second red light organic EL material layer 9, the second green light organic EL material layer 20 and the second blue light organic EL material layer 40, thereby allowing the second red light organic EL material layer 9 to emit red light, the second green light organic EL material layer 20 to emit green light and the second blue light organic EL material layer 40 to emit blue light, and the emitted red light, green light and blue light are mixed to form a white light.

It is seen from the above operation process of the pixel unit provided by the embodiment that, in the pixel unit the white light carrier injection layer can be formed simultaneously when the red light carrier injection layer, the green light carrier injection layer and the blue light carrier injection layer are formed, the white light carrier transmission layer can be formed simultaneously when the red light carrier transmission layer, the green light carrier transmission layer and the blue light carrier transmission layer are formed, the second red light organic EL material layer 9 can be formed simultaneously when the first red light organic EL material layer 8 is formed, the second green light organic EL material layer 20 can be formed simultaneously when the first green light organic EL material layer 10 is formed, and the second blue light organic EL material layer 40 can be formed simultaneously when the first blue light organic EL material layer 30 is formed. As a result, the fabrication of the white sub-pixel unit 4 is finished at the same time when the red sub-pixel unit 5, the green sub-pixel unit 6 and the blue sub-pixel unit 7 are fabricated. That is, the white sub-pixel unit 4 can be formed without extra evaporation operations, thereby preventing the problem that the white sub-pixel units 4 need to be evaporated for several times during the fabrication process which causes an increase of evaporation cost.

Moreover, when the pixel unit provided by the embodiment of the disclosure needs to emit white light, there is no need to drive the red sub-pixel unit 5, the green sub-pixel unit 6 and the blue sub-pixel unit 7 simultaneously. Instead, it can drive the white sub-pixel unit 4 only for the pixel unit emits white light, which helps to reduce the power consumption for driving the OLED to emit white light, thereby increasing a display life of the OLED.

The white sub-pixel unit 4 provided by the embodiment comprises an anode, a cathode and a white light organic material layer disposed between the anode and the cathode. The white light organic material layer comprises the white light carrier injection layer, the white light carrier transmission layer, the second red light organic EL material layer 9, the second green light organic EL material layer 20 and the second blue light organic EL material layer 40.

Herein, the white light carrier injection layer comprises a white light electron injection layer 50 and a white light hole injection layer 60, the white light carrier transmission layer comprises a white light electron transmission layer 70 and a white light hole transmission layer 80; the white light electron transmission layer 70 and the white light hole transmission layer 80 are disposed between the white light electron injection layer 50 and the white light hole injection layer 60. The second red light organic EL material layer 9, the second green light organic EL material layer 20 and the second blue light organic EL material layer 40 are all disposed between the white light electron transmission layer 70 and the white light hole transmission layer 80. The second red light organic EL material layer 9 is in contact with the white light electron transmission layer 70 and the white light hole transmission layer 80 respectively, the second green light organic EL material layer 20 is in contact with the white light electron transmission layer 70 and the white light hole transmission layer 80 respectively, and the second blue light organic EL material layer 40 is in contact with the white light electron transmission layer 70 and the white light hole transmission layer 80 respectively.

It is noted that, each of the cathode, the anode, the white light electron injection layer, the white light hole injection layer, the white light electron transmission layer and the white light hole transmission layer corresponding to the white sub-pixel unit 4 may be an integral structure or a structure comprising a plurality of components not contacting each other. The operation of the white sub-pixel unit corresponding to different situations will be described in the following.

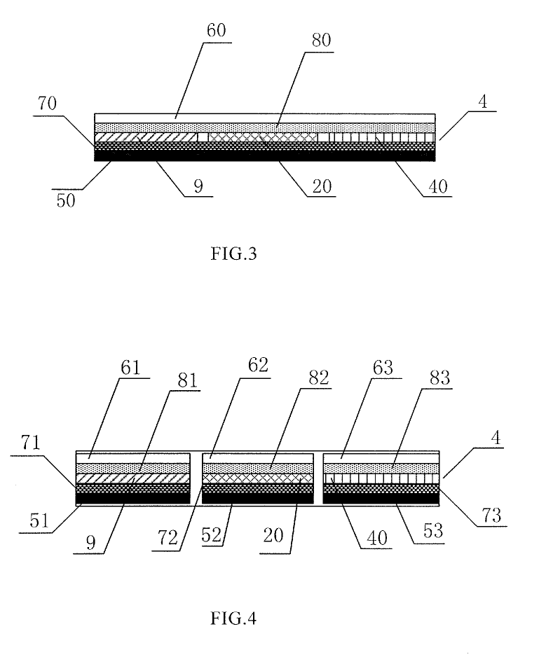

With reference to FIG. 3, when each of the cathode, the anode, the white light electron injection layer, the white light hole injection layer, the white light electron transmission layer and the white light hole transmission layer corresponding to the white sub-pixel unit 4 is an integral structure, the operation of the white sub-pixel unit 4 is as follows: a driving voltage is applied between the anode and cathode of the white sub-pixel unit 4, electrons are generated in the white light electron injection layer 50 under the driving voltage, and the generated electrons are transmitted to the second red light organic EL material layer 9, the second green light organic EL material layer 20 and the second blue light organic EL material layer 40 respectively through the white light electron transmission layer 70. Moreover, holes are generated in the white light hole injection layer 60, and the generated holes are transmitted to the second red light organic EL material layer 9, the second green light organic EL material layer 20 and the second blue light organic EL material layer 40 respectively through the white light hole transmission layer 80. The electrons and holes transmitted to the second red light organic EL material layer 9 recombine to allow the second red light organic EL material layer 9 to emit red light, the electrons and holes transmitted to the second green light organic EL material layer 20 recombine to allow the second green light organic EL material layer 20 to emit green light, the electrons and holes transmitted to the second blue light organic EL material layer 40 recombine to allow the second blue light organic EL material layer 40 to emit blue light, and the emitted red light, green light and blue light are mixed to form white light.

It is seen from the specific structure and operation process of the white sub-pixel unit 4 that, the structure of the white sub-pixel unit 4 is similar to that of the red sub-pixel unit 5, the green sub-pixel unit 6 and the blue sub-pixel unit 7. That is, the structure includes a white light electron injection layer 50, a white light hole injection layer 60, a white light electron transmission 70 and a white light hole transmission layer 80. In this case, when fabricating the pixel units, it can form the red light electron injection layer, the green light electron injection layer, the blue light electron injection layer and the white light electron injection layer 50 through a same patterning process. It can also form the red light hole injection layer, the green light hole injection layer, the blue light hole injection layer and the white light hole injection layer 60 through a same patterning process. The red light electron transmission layer, the green light electron transmission layer, the blue light electron transmission layer and the white light electron transmission layer 70 are formed through a same patterning process. The red light hole transmission layer, the green light hole transmission layer, the blue light hole transmission layer and the white light hole transmission layer 80 are formed through a same patterning process as well. That is, at the same time that the fabrications of the red sub-pixel unit 5, the green sub-pixel unit 6 and the blue sub-pixel unit 7 are finished, the fabrication of the white sub-pixel unit 4 is finished without extra evaporation operations, which allows the fabrication process of the white sub-pixel unit 4 to be simpler and more convenient. Moreover, in a white sub-pixel unit 4 having the above structure, each of the cathode, the anode, the white light electron injection layer 50, the white light hole injection layer 60, the white light electron transmission layer 70 and the white light hole transmission layer 80 corresponding to the white sub-pixel unit 4 is of an integral structure, thus the accuracy of operation is relatively high during the fabrication process using a mask plate.

With reference to FIG. 4, when each of the cathode, the anode, the white light electron injection layer 50, the white light hole injection layer 60, the white light electron transmission layer 70 and the white light hole transmission layer 80 corresponding to the white sub-pixel unit 4 is a structure comprising a plurality of components not in contact with each other, the cathode corresponding to the white sub-pixel unit 4 comprises a first cathode, a second cathode and a third cathode; the anode corresponding to the white sub-pixel unit 4 comprises a first anode, a second anode and a third anode; the white light electron injection layer 50 comprises a first white light electron injection layer 51, a second white light electron injection layer 52 and a third white light electron injection layer 53; the white light hole injection layer 60 comprises a first white light hole injection layer 61, a second white light hole injection layer 62 and a third white light hole injection layer 63; the white light electron transmission layer 70 comprises a first white light electron transmission layer 71, a second white light electron transmission layer 72 and a third white light electron transmission layer 73; and the white light hole transmission layer 80 comprises a first white light hole transmission layer 81, a second white light hole transmission layer 82 and a third white light hole transmission layer 83. In this case, the first cathode, the first anode, the first white light electron injection layer 51, the first white light hole injection layer 61, the first white light electron transmission layer 71 and the first white light hole transmission layer 81 form an integral with the second red light organic EL material layer 9, the second cathode, the second anode, the second white light electron injection layer 52, the second white light hole injection layer 62, the white second light electron transmission layer 72 and the second white light hole transmission layer 82 form an integral with the second green light organic EL material layer 20, and the third cathode, the third anode, the third white light electron injection layer 53, the third white light hole injection layer 63, the third white light electron transmission layer 73 and the third white light hole transmission layer 83 form an integral with the second blue light organic EL material layer 40.

In this case, the operation process of the white sub-pixel unit 4 is as follows: a same driving voltage is applied between the first anode and the first cathode, between the second anode and the second cathode, and between the third anode and the third cathode respectively. Under the driving voltage, electrons are generated in the first white light electron injection layer 51, the second white light electron injection layer 52 and the third white light electron injection layer 53 respectively, the electrons generated by the first white light electron injection layer 51 are transmitted to the second red light organic EL material layer 9 through the first white light electron transmission layer 71, the electrons generated by the second white light electron injection layer 52 are transmitted to the second green light organic EL material layer 20 through the second white light electron transmission layer 72, and the electrons generated by the third white light electron injection layer 53 are transmitted to the second blue light organic EL material layer 40 through the third white light electron transmission layer 73. Moreover, under the driving voltage, holes are generated in the first white light hole injection layer 61, the second white light hole injection layer 62 and the third white light hole injection layer 63 respectively, the holes generated by the first white light hole injection layer 61 are transmitted to the second red light organic EL material layer 9 through the first white light hole transmission layer 81, the holes generated by the second white light hole injection layer 62 are transmitted to the second green light organic EL material layer 20 through the second white light hole transmission layer 82, and the holes generated by the third white light hole injection layer 63 are transmitted to the second blue light organic EL material layer 40 through the third white light hole transmission layer 83. The electrons and holes transmitted to the second red light organic EL material layer 9 recombine to allow the second red light organic EL material layer 9 to emit red light, the electrons and holes transmitted to the second green light organic EL material layer 20 recombine to allow the second green light organic EL material layer 20 to emit green light, the electrons and holes transmitted to the second blue light organic EL material layer 40 recombine to allow the second blue light organic EL material layer 40 to emit blue light, and the emitted red light, green light and blue light are mixed to form white light.

It is seen from the specific structure and operation process of the white sub-pixel unit 4 that, when fabricating pixel units, it can form the red light electron injection layer, the green light electron injection layer, the blue light electron injection layer, the first white light electron injection layer 51, the second white light electron injection layer 52 and the third white light electron injection layer 53 through a same patterning process The red light hole injection layer, the green light hole injection layer, the blue light hole injection layer, the first white light hole injection layer 61, the second white light hole injection layer 62 and the third white light hole injection layer 63 are formed through a same patterning process The red light electron transmission layer, the green light electron transmission layer, the blue light electron transmission layer, the first white light electron transmission layer 71, the second white light electron transmission layer 72 and the third white light electron transmission layer 73 are formed through a same patterning process. The red light hole transmission layer, the green light hole transmission layer, the blue light hole transmission layer, the first white light hole transmission layer 81, the second white light hole transmission layer 82 and the third white light hole transmission layer 83 are formed through a same patterning process. That is, at the same time that the red sub-pixel unit 5, the green sub-pixel unit 6 and the blue sub-pixel unit 7 are fabricated, the fabrication of the white sub-pixel unit 4 is finished without extra evaporation operations, which allows the fabrication process of the white sub-pixel unit 4 to be simpler and more convenient.

Moreover, in a white sub-pixel unit 4 having the above structure, when a same driving voltage is applied between the first anode and the first cathode, between the second anode and the second cathode, and between the third anode and the third cathode respectively, correspondingly, an amount of the electrons going into the second red light organic EL material layer 9, an amount of the electrons going into the green light organic EL material layer 20 and an amount of the electrons going into the blue light organic EL material layer 40 are equal to each other, and an amount of the holes going into the second red light organic EL material layer 9, an amount of the holes going into the green light organic EL material layer 20 and an amount of the holes going into the blue light organic EL material layer 40 are equal to each other, which allows the lights emitted by the second red light organic EL material layer 9, the green light organic EL material layer 20 and the blue light organic EL material layer 40 respectively to have homogeneous luminance and to be mixed into a white light having a better effect.

It is noted that, gaps are disposed between the second red light organic EL material layer 9, the second green light organic EL material layer 20 and the second blue light organic EL material layer 40. On one hand, the gaps are configured for placing a corresponding driving circuit. On the other hand, during the fabrication process of the white sub-pixel unit, the above configuration can prevent the second red light organic EL material layer 9, the second green light organic EL material layer 20 and the second blue light organic EL material layer 40 from overlapping each other which may compromise a normal display. However, the width of gaps is not to be too large, otherwise, the emitting area of the white sub-pixel unit 4 may be reduced, which may compromise the normal display effect.

In the pixel unit provided by the embodiment, areas of the organic EL material layers corresponding to the red sub-pixel unit 5, the green sub-pixel unit 6, the blue sub-pixel unit 7 and the white sub-pixel unit 4 may affect a luminance of the pixel unit.

In order to describe the effect of the areas of the organic EL material layers corresponding to the red sub-pixel unit 5, the green sub-pixel unit 6, the blue sub-pixel unit 7 and the white sub-pixel unit 4 on the luminous effect of the pixel unit more clearly, some parameters are defined as follows: an area of the first red light organic EL material layer 8 is X_{R}, an area of the first green light organic EL material layer 10 is X_{G}, an area of the first blue light organic EL material layer 30 is X_{B}, an area of the second red light organic EL material layer 9 is W_{R}, an area of the second green light organic EL material layer 20 is W_{G}, and an area of the second blue light organic EL material layer 40 is W_{B}.

When an image is displayed, proportions of the areas of various sub-pixel units should meet some requirements to prevent the areas of various sub-pixel units from being too large or too small which may cause that the pixel unit cannot realize the normal display. In the pixel unit provided by the embodiment, the areas of various sub-pixel units should meet the following requirements:

$$0.01 < \frac{{X}_{R}}{{W}_{R} + {W}_{G} + {W}_{B}} < 100 ;$$

$$0.01 < \frac{{X}_{G}}{{W}_{R} + {W}_{G} + {W}_{B}} < 100 ;$$

$$0.01 < \frac{{X}_{B}}{{W}_{R} + {W}_{G} + {W}_{B}} < 100.$$

In this case, areas of the organic EL material layers corresponding to the red sub-pixel unit 5, the green sub-pixel unit 6, the blue sub-pixel unit 7 and the white sub-pixel unit 4 have an appropriate proportion, thereby realizing the normal display of the pixel unit.

Moreover, on the premise that the image can be display normally, in order to adapt different practical conditions, it can limit the areas of the red sub-pixel unit 5, the green sub-pixel unit 6, the blue sub-pixel unit 7 and the white sub-pixel unit 4 so as to realize different luminance. Some of embodiments is provided as follows so as to describe the corresponding effects generated by different areas of the organic EL material layers corresponding to various sub-pixel units in detail.

### Embodiment 1

With reference to FIG. 5, when

$$\frac{{X}_{R}}{{W}_{R}} = \frac{{X}_{G}}{{W}_{G}} = \frac{{X}_{B}}{{W}_{B}} and \frac{{X}_{R}}{{W}_{R}} > 1 ,$$

it takes

$$\frac{{X}_{R}}{{W}_{R}} = \frac{{X}_{G}}{{W}_{G}} = \frac{{X}_{B}}{{W}_{B}} = 3$$

as an example. In this case, X_{B}:X_{G}:X_{B}:(W_{R}+W_{G}+W_{B})=3:3:3:3=1:1:1:1, that is, X_{R}=X_{G}=X_{B}=(W_{R}+W_{G}+W_{B}). Due to the above fact, when a same driving voltage is applied to various sub-pixel units, corresponding luminance of various sub-pixel units are of the same, thereby allowing the luminance of the pixel unit comprising various sub-pixel units to be more homogeneous.

### Embodiment 2

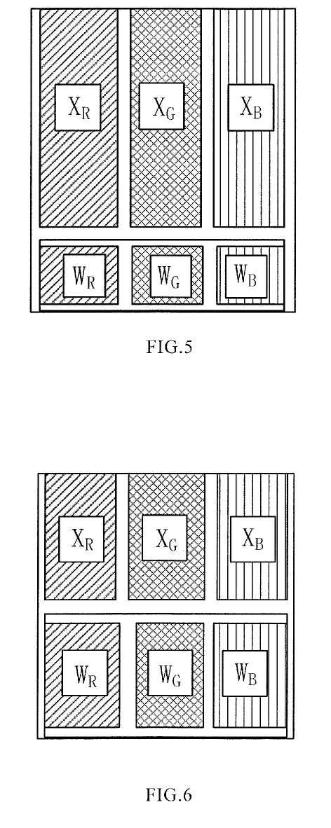

With reference to FIG. 6, when

$$\frac{{X}_{R}}{{W}_{R}} = \frac{{X}_{G}}{{W}_{G}} = \frac{{X}_{B}}{{W}_{B}} = 1 , \\ {X}_{R} : {X}_{G} \text{:} {X}_{B} \text{:} ( {W}_{R} + {W}_{G} + {W}_{B} ) = 1 \text{:} 1 \text{:} 1 \text{:} 3 , that is , \\ {X}_{R} = {X}_{G} = {X}_{B} = \frac{1}{3} ( {W}_{R} + {W}_{G} + {W}_{B} ) .$$

In this case, areas of the organic EL material layers corresponding to the red sub-pixel unit 5, the green sub-pixel unit 6 and the blue sub-pixel unit 7 are equal to each other, and the area of the organic EL material layer corresponding to the white sub-pixel unit 4 is relatively large. Due to the above fact, when a same driving voltage is applied to the red sub-pixel unit 5, the green sub-pixel unit 6 and the blue sub-pixel unit 7, the luminance of the lights emitted by the red sub-pixel unit 5, the green sub-pixel unit 6 and the blue sub-pixel unit 7 are of the same, and the lights can be mixed to realize a more homogeneous color display. However, when a driving voltage is applied to the white sub-pixel unit 4, the white light emitted by the white sub-pixel unit 4 has a relatively higher luminance.

### Embodiment 3

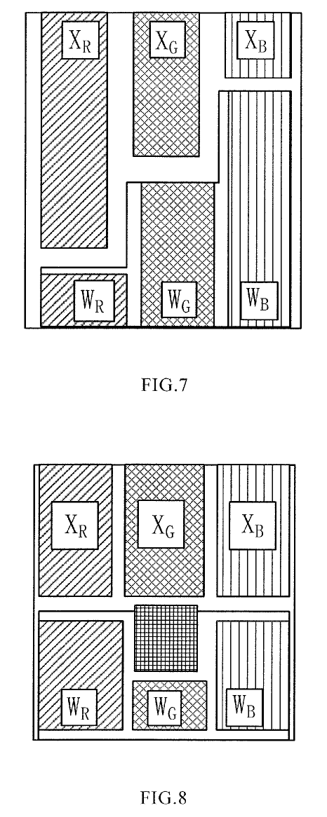

With reference to FIG. 7, when

$$\frac{{X}_{R}}{{W}_{R}} \neq \frac{{X}_{G}}{{W}_{G}} , \frac{{X}_{R}}{{W}_{R}} \neq \frac{{X}_{B}}{{W}_{B}} , \frac{{X}_{G}}{{W}_{G}} \neq \frac{{X}_{B}}{{W}_{B}} ,$$

it takes

$$\frac{{X}_{R}}{{W}_{R}} = 4 , \frac{{X}_{G}}{{W}_{G}} = 1 , \frac{{X}_{B}}{{W}_{B}} = \frac{1}{4}$$

as an example. In this case, X_{R}:X_{G}:X_{B}:(W_{R}+W_{G}+W_{B})=4:2:1:6. In comparison with the embodiment 1, the area of the organic EL material layer corresponding to the white sub-pixel unit 4 is relatively large. When a driving voltage is applied to the white sub-pixel unit 4, the white sub-pixel unit 4 can also emit white light having a relatively high luminance. Furthermore, the pixel unit may be used in medical devices to fully take advantage of high luminance display effect.

### Embodiment 4

With reference to FIG. 8, when

$$\frac{{X}_{R}}{{W}_{R}} = \frac{{X}_{B}}{{W}_{B}} and \frac{{X}_{R}}{{W}_{R}} < \frac{{X}_{G}}{{W}_{G}} ,$$

it takes

$$\frac{{X}_{R}}{{W}_{R}} = \frac{{X}_{B}}{{W}_{B}} = 1 and \frac{{X}_{R}}{{W}_{R}} < \frac{{X}_{G}}{{W}_{G}}$$

as an example. As life spans of the organic EL materials emitting red light and blue light are relatively short and a life span of the organic EL material emitting green light is relatively long, under the premise that a whole life span of the pixel unit will not be compromised much, it is possible to reduce the area of W_{G} appropriately such that the spare space left in the white sub-pixel unit 4 can accommodate the driving circuit which is originally disposed between the adjacent sub-pixel units of the pixel unit, thereby shortening the distance between the adjacent sub-pixel units, increasing an aperture ratio of the pixel unit, and increasing the light transmittance efficient.

A method for fabricating the pixel unit is further provided by the embodiment of the disclosure, and the method comprises: forming a red light carrier injection layer, a green carrier injection layer, a blue light carrier injection layer and a white light carrier injection layer in a same patterning process; forming a red light carrier transmission layer, a green light carrier transmission layer, a blue light carrier transmission layer and a white light carrier transmission layer in a same patterning process; forming the first red light organic EL material layer 8 and the second red light organic EL material layer 9 in a same patterning process; forming the first green light organic EL material layer 10 and the second green light organic EL material layer 20 in a same patterning process; forming the first blue light organic EL material layer 30 and the second blue light organic EL material layer 40 in a same patterning process.

The white light carrier injection layer of the pixel unit comprises the white light electron injection layer 50 and the white light hole injection layer 60, the white light carrier transmission layer comprises the white light electron transmission layer 70 and the white light hole transmission layer 80; the red light carrier injection layer comprises a red light electron injection layer and a red light hole injection layer, the red light carrier transmission layer comprises a red light electron transmission layer and a red light hole transmission layer; the green light carrier injection layer comprises a green light electron injection layer and a green light hole injection layer, the green light carrier transmission layer comprises a green light electron transmission layer and a green light hole transmission layer; the blue light carrier injection layer comprises a blue light electron injection layer and a blue light hole injection layer, the blue light carrier transmission layer comprises a blue light electron transmission layer and a blue light hole transmission layer.

During the fabricating process of the pixel unit, the method comprises: forming the white light electron injection layer 50, the red light electron injection layer, the green light electron injection layer and the blue light electron injection layer in a same patterning process; forming the white light electron transmission layer 70, the red light electron transmission layer, the green light electron transmission layer and the blue light electron transmission layer in a same patterning process; forming the white light hole transmission layer 80, the red light hole transmission layer, the green light hole transmission layer and the blue light hole transmission layer in a same patterning process; and forming the white light hole injection layer 60, the red light hole injection layer, the green light hole injection layer and the blue light hole injection layer in a same patterning process.

Moreover, during the fabricating process of the pixel unit, the method comprises: forming an anode corresponding to the red sub-pixel unit 5, an anode corresponding to the green sub-pixel unit 6, an anode corresponding to the blue sub-pixel unit 7 and an anode corresponding to the white sub-pixel unit 4 in a same patterning process; and forming a cathode corresponding to the red sub-pixel unit 5, a cathode corresponding to the green sub-pixel unit 6, a cathode corresponding to the blue sub-pixel unit 7 and a cathode corresponding to the white sub-pixel unit 4 in a same patterning process.

It can be seen from the fabrication method that, the fabrication of the white sub-pixel unit 4 is finished without extra evaporation operations, which allows the fabricating process of the white sub-pixel unit 4 to be simpler and more convenient.

In order to describe the method for fabricating the pixel unit more clearly, a specific embodiment is provided in the following.

### Embodiment 5

Step S1: forming an anode corresponding to the red sub-pixel unit 5, an anode corresponding to the green sub-pixel unit 6, an anode corresponding to the blue sub-pixel unit 7 and an anode corresponding to the white sub-pixel unit 4 on a substrate in a same patterning process.

Step S2: forming the red light hole injection layer, the green light hole injection layer, the blue light hole injection layer and the white light hole injection layer in the corresponding anodes.

Step S3: forming the red light hole transmission layer, the green light hole transmission layer, the blue light hole transmission layer and the white light hole transmission layer on the corresponding hole injection layers.

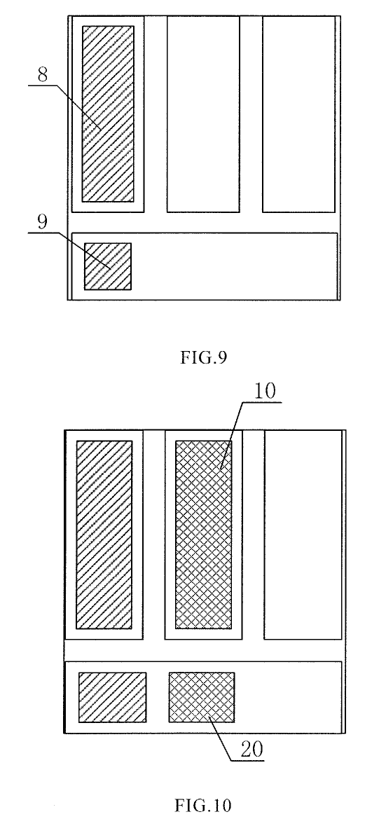

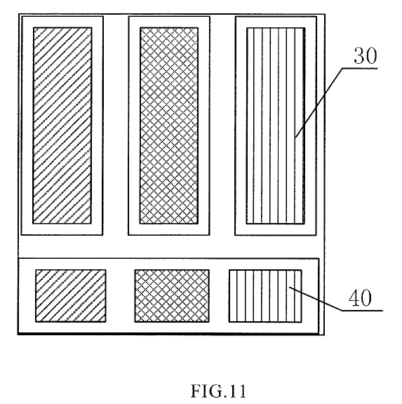

Step S4: with reference to FIG. 9, evaporating the first red light organic EL material layer 8 and the second red light organic EL material layer 9 on corresponding hole transmission layers in a same patterning process; with reference to FIG. 10, evaporating the first green light organic EL material layer 10 and the second green light organic EL material layer 20 on corresponding hole transmission layers in a same patterning process; and with reference to FIG. 11, evaporating the first blue light organic EL material layer 30 and the second blue light organic EL material layer 40 on corresponding hole transmission layers in a same patterning process.

Step S5: forming the red light electron transmission layer, the green light electron transmission layer, the blue light electron transmission layer and the white light electron transmission layer on corresponding organic EL material layers in a same patterning process.

Step S6: forming the red light electron injection layer, the green light electron injection layer, the blue light electron injection layer and the white light electron injection layer on corresponding electron transmission layers in a same patterning process.

Step S7: forming the cathode corresponding to the red sub-pixel unit 5, the cathode corresponding to the green sub-pixel unit 6, the cathode corresponding to the blue sub-pixel unit 7 and the cathode corresponding to the white sub-pixel unit 4 on corresponding electron injection layers in a same patterning process.

It is noted that, the step of forming the first red light organic EL material layer 8, the second red light organic EL material layer 9, the first green light organic EL material layer 10, the second green light organic EL material layer 20, the first blue light organic EL material layer 30 and the second blue light organic EL material layer 40 in step S4 can be realized by using a mask plate provided with slit which has a corresponding shape of the layer pattern.

The embodiment of the disclosure further provides a display device comprising the pixel unit provided by the embodiment. The display device has a same beneficial effect as the pixel unit, and it will not be elaborated herein.

What is described above is related to the illustrative embodiments of the disclosure only and not limitative to the scope of the disclosure; the scopes of the disclosure are defined by the accompanying claims.

The present application claims priority from Chinese Application No. 201510714052.X, filed on Oct. 28, 2015, the disclosure of which is incorporated herein by reference in its entirety.

What is claimed is:

1. A pixel unit, comprising a red sub-pixel unit, a green sub-pixel unit, a blue sub-pixel unit and a white sub-pixel unit; wherein the red sub-pixel unit comprises a red light carrier injection layer, a red light carrier transmission layer and a first red light organic electro luminescence (EL) material layer; the green sub-pixel unit comprises a green light carrier injection layer, a green light carrier transmission layer and a first green light organic EL material layer; the blue sub-pixel unit comprises a blue light carrier injection layer, a blue light carrier transmission layer and a first blue light organic EL material layer; and the white sub-pixel unit comprises a white light carrier injection layer, a white light carrier transmission, a second red light organic EL material layer, a second green light organic EL material layer and a second blue light organic EL material layer;
wherein the white light carrier injection layer is formed in a same patterning process as the red light carrier injection layer, the green carrier injection layer and the blue light carrier injection layer; the white light carrier transmission layer is formed in a same patterning process as the red light carrier transmission layer, the green light carrier transmission layer and the blue light carrier transmission layer; the second red light organic EL material layer is formed in a same patterning process as the first red light organic EL material layer; the second green light organic EL material layer is formed in a same patterning process as the first green light organic EL material layer; the second blue light-organic EL material layer is formed in a same patterning process as the first blue light organic EL material layer.

2. The pixel unit of claim 1, wherein an area of the first red light organic EL material layer is X_{R}, an area of the first green light organic EL material layer is X_{G}, an area of the first blue light organic EL material layer is X_{B}, an area of the second red light organic EL material layer is W_{R}, an area of the second green light organic EL material layer is W_{G}, and an area of the second blue light organic EL material layer is W_{R}; wherein
$$0.01 < \frac{{X}_{R}}{{W}_{R} + {W}_{G} + {W}_{B}} < 100 ;$$
$$0.01 < \frac{{X}_{R}}{{W}_{R} + {W}_{G} + {W}_{B}} < 100 ;$$
$$0.01 < \frac{{X}_{R}}{{W}_{R} + {W}_{G} + {W}_{B}} < 100.$$

3. The pixel unit of claim 2, wherein,
$$\frac{{X}_{R}}{{W}_{R}} = \frac{{X}_{G}}{{W}_{G}} = \frac{{X}_{B}}{{W}_{B}} , and \frac{{X}_{R}}{{W}_{R}} \geq 1.$$

4. The pixel unit of claim 2, wherein
$$\frac{{X}_{R}}{{W}_{R}} \neq \frac{{X}_{G}}{{W}_{G}} , \frac{{X}_{R}}{{W}_{R}} \neq \frac{{X}_{B}}{{W}_{B}} , \frac{{X}_{G}}{{W}_{G}} \neq \frac{{X}_{B}}{{W}_{B}} .$$

5. The pixel unit of claim 2, wherein
$$\frac{{X}_{R}}{{W}_{R}} = \frac{{X}_{B}}{{W}_{B}} , and \frac{{X}_{R}}{{W}_{R}} < \frac{{X}_{G}}{{W}_{G}} .$$

6. The pixel unit of claim 1, wherein the white light carrier injection layer comprises a white light electron injection layer and a white light hole injection layer, the white light carrier transmission layer comprises a white light electron transmission layer and a white light hole transmission layer; the second red light organic EL material layer, the second green light organic EL material layer and the second blue light organic EL material layer are all disposed between the white light electron transmission layer and the white light hole transmission layer; the second red light organic EL material layer is in contact with the white light electron transmission layer and the white light hole transmission layer respectively, the second green light organic EL material layer is in contact with the white light electron transmission layer and the white light hole transmission layer respectively, and the second blue light organic EL material layer is in contact with the white light electron transmission layer and the white light hole transmission layer respectively.

7. A method for fabricating a pixel unit, wherein the pixel unit comprises a red sub-pixel unit, a green sub-pixel unit, a blue sub-pixel unit and a white sub-pixel unit; the red sub-pixel unit comprises a red light carrier injection layer, a red light carrier transmission layer and a first red light organic EL material layer; the green sub-pixel unit comprises a green light carrier injection layer, a green light carrier transmission layer and a first green light organic EL material layer; the blue sub-pixel unit comprises a blue light carrier injection layer, a blue light carrier transmission layer and a first blue light organic EL material layer; the white sub-pixel unit comprises a white light carrier injection layer, a white light carrier transmission, a second red light organic EL material layer, a second green light organic EL material layer and a second blue light organic EL material layer; and the method comprises:
forming the red light carrier injection layer, the green carrier injection layer, the blue light carrier injection layer and the white light carrier injection layer in a same patterning process;
forming the red light carrier transmission layer, the green light carrier transmission layer, the blue light carrier transmission layer and the white light carrier transmission layer in a same patterning process;
forming the first red light organic EL material layer and the second red light organic EL material layer in a same patterning process;
forming the first green light organic EL material layer and the second green light organic EL material layer in a same patterning process;
forming the first blue light organic EL material layer and the second blue light organic EL material layer in a same patterning process.

8. The method of claim 7, wherein the white light carrier injection layer of the pixel unit comprises a white light electron injection layer and a white light hole injection layer, the white light carrier transmission layer comprises a white light electron transmission layer and a white light hole transmission layer; the red light carrier injection layer comprises a red light electron injection layer and a red light hole injection layer, the red light carrier transmission layer comprises a red light electron transmission layer and a red light hole transmission layer; the green light carrier injection layer comprises a green light electron injection layer and a green light hole injection layer, the green light carrier transmission layer comprises a green light electron transmission layer and a green light hole transmission layer; the blue light carrier injection layer comprises a blue light electron injection layer and a blue light hole injection layer, the blue light carrier transmission layer comprises a blue light electron transmission layer and a blue light hole transmission layer;
wherein the white light electron injection layer, the red light electron injection layer, the green light electron injection layer and the blue light electron injection layer are formed in a same patterning process;
wherein the white light electron transmission layer, the red light electron transmission layer, the green light electron transmission layer and the blue light electron transmission layer are formed in a same patterning process;
wherein the white light hole transmission layer, the red light hole transmission layer, the green light hole transmission layer and the blue light hole transmission layer are formed in a same patterning process;
wherein the white light hole injection layer, the red light hole injection layer, the green light hole injection layer and the blue light hole injection layer are formed in a same patterning process.

9. The method of claim 8, comprising an anode corresponding to the red sub-pixel unit, an anode corresponding to the green sub-pixel unit, an anode corresponding to the blue sub-pixel unit and an anode corresponding to the white sub-pixel unit are formed in a same patterning process; and a cathode corresponding to the red sub-pixel unit, a cathode corresponding to the green sub-pixel unit, a cathode corresponding to the blue sub-pixel unit and a cathode corresponding to the white sub-pixel unit are formed in a same patterning process.

10. A display device comprising the pixel unit of claim 1.
